(19) United States
(12) Patent Application Publication
(10) Pub. No.: US 2006/0180921 A1
(43) Pub. Date: Aug. 17, 2006

(54) Method for producing an FBGA component and substrate for carrying out the method

(76) Inventors: Steffen Kroehnert, Dresden (DE); Knut Kahlisch, Dresden (DE); Ruediger Uhlmann, Dresden (DE); Carsten Bender, Muenchen (DE)

Correspondence Address: SLATER & MATSIL LLP, 17950 PRESTON ROAD, SUITE 1000, DALLAS, TX, 75252, US

(21) Appl. No.: 11/336,615

(22) Filed: Jan. 20, 2006

(30) Foreign Application Priority Data
Jan. 20, 2005 (DE) 10 2005 002 862.4

(51) Int. Cl. H01L 23/28; H01L 21/56

(52) U.S. Cl. 257/701; 438/126; 438/127; 257/787

(57) ABSTRACT

A semiconductor component includes a substrate having a chip side and a solder ball side. A semiconductor chip is mounted on the chip side of a substrate. The semiconductor chip is electrically conductively connected to a conductor structure on the substrate. Ball pads are disposed over the solder ball side of the substrate. The ball pads are electrically conductively connected to the conductor structure and suitable for application of solder balls. A mask made from a soldering resist is disposed on the solder ball side. A sealing region at a surface of the solder ball side of the substrate is provided with seal elements for a sealing connection to an encapsulation mold on the surface of the solder ball side.

This application claims priority to German Patent Application 10 2005 002 862.4, which was filed Jan. 20, 2005, and is incorporated herein by reference.

### TECHNICAL FIELD

The invention relates to the field of semiconductor production. In particular, the invention relates to the enveloping of semiconductor chips after their mounting on a carrier substrate.

### BACKGROUND

During the production of semiconductor components, semiconductor chips are mounted on substrates. In this case, it is also possible for a plurality of semiconductor chips to be mounted one above another. A substrate has a conductor structure serving for connecting the semiconductor chip to an external circuitry. The conductor structure comprises conductive tracks, contact pads and ball pads.

FBGA housings (FBGA=Fine Ball Grid Array) are known for connecting the conductor structures to an external circuitry. In this case, the substrate has a chip side, on which the chip or the chip stack is mounted. The substrate has a solder ball side opposite to the chip side. The conductor structures, or at the very least parts of the conductor structures, are arranged on the solder ball side.

In one embodiment of FBGA housings, the semiconductor chip (the bottom semiconductor chip in the case of a chip stack) is mounted onto the chip side of the substrate with its bonding pads directed toward the chip side of the substrate. In this case, a bonding channel is provided in the substrate. The bonding channel comprises an opening in the substrate, preferably in the form of an elongated slot or a quadrangular hole. Through the bonding channel, wire bridges are drawn from the bonding pads on the semiconductor chip to corresponding contact islands in the conductor structure on the solder ball side for the purpose of electrically connecting the semiconductor chip to the conductive tracks of the conductor structure.

The ball pads of the conductor structure are arranged on the solder ball side. The ball pads are provided with solder balls via which, in a later process, the semiconductor component can then be mounted and electrically conductively connected to the external circuitry, for example on a printed circuit board. For this purpose, the solder is heated until it melts. In order to prevent the solder from then flowing away from the solder balls in an uncontrolled manner, the solder ball side is coated with a soldering resist, which is patterned so as to avoid such an uncontrolled flowing away of solder during the later mounting process.

In order to stabilize the entire semiconductor component, the latter is provided with a housing made of a mold compound. The housing comprises an upper housing part on the chip side and—in the case of FBGA housings with a bonding channel—of a lower housing part on the solder ball side. The lower housing part in particular also protects the bonding wires led through the bonding channel by virtue of the bonding channel being filled with mold compound with molding of the lower housing part and the bonding wires thus being enclosed by mold compound.

Encapsulation molds having the negative mold of the housing parts are used for the molding of these housing parts. Around the negative mold of a housing part, the encapsulation mold is provided with a sealing web. During the production of the housing parts, the encapsulation mold is placed onto the respective substrate side and pressed with a pressure force onto the respective substrate side. In this case, the negative molds enclose the parts of the semiconductor component to be encapsulated. Mold compound is then forced into the negative molds. In this case, the sealing web and the pressure force are intended to prevent mold compound from flowing out of the negative mold. It has been shown in practice, however, that this is accomplished only inadequately.

This is because the mold compound is heated to a temperature of approximately 180° C. during encapsulation, as a result of which it has very low viscosity and as a result emerges between the substrate side and sealing web. Even when there is good sealing, so-called “bleeding” still takes place, during which components of the mold compound, such as resin components, pass through the sealing.

This is disadvantageous particularly when molding the lower housing part on the solder ball side, since this escaping mold compound may also pass onto the solder balls or in the vicinity thereof and thus adversely influence later mounting processes, such as soldering-on. This problem is exacerbated by the fact that in FBGA housings having a lower housing part, the conductor structure is quite generally arranged on the solder ball side. The conductor structure comprises metal conductive tracks elevated over the rest of the substrate surface. As a result, leakages occur between the encapsulation mold and the substrate surface on the solder ball side since the surface is not even.

Various measures are possible for avoiding this problem. Firstly, it is possible to increase the pressure force. This may be done in particular by increasing the transfer pressure, that is to say by pressing the encapsulation molds for the upper and lower housing parts against one another.

However, increasing the pressure force has the disadvantage that the substrate is exposed to a very high mechanical stress, which may result in the substrate breaking.

A further possibility for improving the seal between encapsulation mold and substrate surface consists in the sealing webs of the encapsulation mold for the lower housing parts being kept very narrow, to the point where they have the form of a cutting edge. As a result, the pressure per unit area between sealing web and substrate surface is increased and the sealing webs can penetrate into the substrate surface of the solder ball side, that is to say into the soldering resist situated thereon.

Such a configuration of encapsulation molds requires very small manufacturing tolerances, which leads to costly manufacture. On the other hand, the service lives of the encapsulation molds are short since the slightest damage to the sealing web results in the encapsulation mold being unusable. Finally, the problem of the substrate breaking is increased even further when the narrow webs are combined with increasing the pressure force.

Fixing the encapsulation mold by means of vacuum has furthermore been provided. This leads to a pressure force distribution that is as uniform as possible, but does not avoid the risk of the substrate breaking.

Finally, one possibility for reducing bleeding consists in using mold compound having a lower viscosity. A flowability reduced in this way has the effect that it is more difficult for mold compound to emerge through leakages between the encapsulation mold and the surface on the solder ball side. However, devising a mold compound of this type is associated with considerable costs. Moreover, the lower flowability may give rise to problems during the molding process itself.

### SUMMARY OF THE INVENTION

Embodiments of the invention relate to a method in which a semiconductor chip is mounted on a chip side of a substrate. The semiconductor chip is electrically conductively connected to a conductor structure on the substrate. Solder balls are applied to ball pads of the conductor structure on a solder ball side of the substrate. The solder ball side is provided with a mask made of a soldering resist. An encapsulation mold for producing a lower housing part is pressed onto the solder ball side and the encapsulation mold is filled with encapsulation composition, further called mold compound. Other embodiments of the invention relate to a substrate for carrying out the method.

In one aspect the invention improves a sealing of the encapsulation mold for the lower housing part on the solder ball side with respect to the substrate surface thereof and in so doing reducing the risk of the substrate breaking and the production outlay on encapsulation molds and increasing the service lives thereof.

According to embodiments of the invention, a method is provided wherein the substrate surface on the solder ball side, at least in the region in which the encapsulation mold is placed onto the substrate surface of the solder ball side, is formed as a sealing region in such a way that the substrate surface is provided with seal elements. The encapsulation mold enters into a sealing connection with the seal elements. Thus, the seal between the encapsulation mold and the substrate surface, in contrast to the prior art, is not realized by the encapsulation mold but by the substrate. As a result, the requirements made of the encapsulation mold are reduced and possible damage to the encapsulation mold thus has a considerably small influence on the seal than in the case of the prior art. The seal between the substrate and the encapsulation mold is realized by the respective substrate. If possible leakages occur, then these faults will only occur at one substrate and will not be reproduced in a plurality of substrates.

In one variant of the method according to embodiments of the invention, it is provided that the conductor structure is patterned in such a way that there is a minimum lateral distance between the individual conductive tracks in the sealing region. The conductive tracks are thus formed in a particular manner at least in the sealing region. This may be done, for example, by virtue of the conductive tracks having area extensions in this region, so that the individual conductive tracks come as close as a minimum distance to one another. What is thus achieved is that the conductive tracks form almost a closed surface in the sealing region, whereby the sealing effect is considerably improved.

In a further variant of the method according to embodiments of the invention, it is provided that the surface of the soldering resist is patterned in uneven fashion at least in the sealing region. When the encapsulation tool is brought close to the surface of the soldering resist, this will then be placed first on the most elevated parts of the surface structure. The pressure force thus acts with a particularly large pressure per unit area in these regions, as a result of which the soldering resist is pressed into the regions of the adjacent depressions. Consequently, the soldering resist itself creates a sealing area between the encapsulation mold and the substrate surface, in this case the soldering resist surface.

In this case, it is possible for the unevennesses in the surface of the soldering resist to be patterned by means of a photolithographic process or by means of a mechanical process, in particular by means of a pressing operation.

Both variants bring about the same effect, namely that the most elevated parts are pressed into the less elevated “valleys” by the encapsulation mold, since the soldering resist has a certain flexibility.

With regard to the structure of the surface, a groove structure may be produced in which longitudinally extended depressions and elevations alongside one another run in one direction. This groove or wave structure brings about the effect of pressing “wave crests” into “wave troughs” if the encapsulation tool is emplaced in some way transversely with respect to the direction. For this reason, it is particularly expedient that in regions of the sealing region, which have a longitudinal extent, the depressions and elevations are introduced transversely with respect to the direction of the longitudinal extent.

With regard to the form of the grooves, an undulatory form and a meandering form or a zigzag form of the cross-section are possible.

In order to produce a certain independence between the uneven structure and the direction of the press-on areas of the encapsulation mold, another variant of the method according to embodiments of the invention provides for the surface of the grid structure to be produced in a manner such that first depressions and elevations lying alongside one another, which run in a first direction, cross second depressions and elevations lying alongside one another, which run in a second direction. In this variant, a projecting elevation of the soldering resist will always be able to be pressed into an adjacent depression, thereby considerably improving the seal.

A third possibility for the configuration of the unevennesses in the substrate surface makes use of a disordered unevenness by virtue of the surface being textured. In this case, it assumes an orange peel form, which can give rise to elevations and depressions alongside one another in a disordered manner.

This textured surface may be produced, in one instance, by the soldering resist mask being exposed to a thermal process after application. On account of this thermal process, surface alterations take place in a manner such that parts of the soldering resist contract. This contraction then gives rise to a nonuniformly uneven surface.

Another variant of the production of a textured surface consists in the fact that a chemical or mechanical admixture that brings about the unevennesses in the surface is added to the soldering resist before application.

In the case of a chemical admixture, this admixture will quite generally be distributed nonuniformly in the soldering resist and then lead to nonuniform applications of resist or contraction of the resist in regions.

The admixture of mechanical means may involve flexible admixtures that have a certain granularity. As a result of this admixture, on the one hand the surface becomes uneven, and, on the other hand, the flexibility of these admixtures has the effect that the surface of the soldering resist mask approximates very well to the encapsulation mold.

Finally, there is also the possibility of the soldering resist being applied in uneven fashion. It will be endeavored, quite generally, to configure the soldering resist with a certain planarity, for example by means of a spin-off method or a uniform injection method. In the case of the deliberately uneven application of the resist, the injection application of the resist, in particular, will be successful. This is because if the injection is performed with a resist having higher viscosity, then the individual injected droplets are compensated for inadequately on the surface and an unevenness thereby arises which, for its part, in turn leads to the compensation of the soldering resist surface upon contact of the encapsulation mold in the region of the sealing area.

Another possibility for the configuration of the sealing area consists in the substrate surface requiring a layer made of elastic material in the sealing region. The layer may be applied as an elevation. A silicone, which has a very good elasticity, is particularly suitable in the case of this sealing elevation. A rubberlike seal is thus provided directly in the region where the encapsulation mold makes contact with the substrate surface, so that even extremely low pressure forces already lead to an excellent seal.

All the above-mentioned measures do not disturb subsequent processes, in the case of which, after all, it is merely important that the solder balls are impeded from flowing away when melting by the soldering resist. The surface structure, which the soldering resist, has is independent for this outcome. Uneven elevations, as provided in the last-mentioned variant of the method, also effect just as little disturbance.

Another aspect of the invention provides a further method wherein the substrate surface on the solder ball side between the region in which the encapsulation mold is placed onto the substrate surface of the solder ball side and the ball pads, a trench is introduced into the substrate surface in such a way that this trench prevents a flow of material from the mold compound in the direction of the ball pads.

Firstly, mold compound or material secreted from the mold compound is collected by the trench and thus prevented from continuing to flow. It has additionally been shown that the edges of the trench, on account of the adhesion forces acting, constitute a flow resistance for the flowing material, with the result that flowing is impeded.

A further aspect provides that the substrate surface on the solder ball side, at least in the region in which the encapsulation mold is placed onto the substrate surface of the solder ball side, is formed as a sealing region in such a way that the substrate surface is provided with seal elements, and at the substrate surface on the solder ball side between the region in which the encapsulation mold is placed onto the substrate surface of the solder ball side and the ball pads, a trench is introduced into the substrate surface in such a way that this trench prevents a flow of material from the mold compound in the direction of the ball pads.

Consequently, the seal elements make it more difficult for material to emerge from the mold compound. If “bleeding” should nevertheless occur, the flowing of the material that has emerged in the direction of the ball pads is stopped by the trench.

In terms of an arrangement, embodiments of the invention also provide a substrate of the type mentioned in the introduction in which the substrate surface, on the solder ball side, has a sealing region for an encapsulation mold that is to be emplaced during production, in which region the substrate surface is provided with seal elements for sealing connection to the encapsulation mold. With a substrate of this type, the substrate manufacturer can already take care to ensure that the tightness between the encapsulation mold and the substrate surface is ensured in a later encapsulation process.

In one refinement of the substrate according to embodiments of the invention, it is provided that the conductor structure is patterned in such a way that there is a minimum lateral distance between the individual conductive tracks in the sealing region. In the case of this refinement, the conductive tracks, as an essential part of the substrate on the solder ball side, provide a smoothest possible surface below the soldering resist mask, with the result that the soldering resist mask is configured in essentially planar fashion on its top side. Additional depressions, which are caused by distances between the elevated conductive tracks and are imaged in the soldering resist mask, are thus avoided.

In a further refinement of the substrate according to embodiments of the invention, it is provided that the surface of the soldering resist is patterned in uneven fashion at least in the sealing region. This uneven patterning of the soldering resist exploits the plastic property thereof and the soldering resist can be deformed below the encapsulation mold so as to give rise to a best possible sealing area between the substrate surface, that is to say between the surface of the soldering resist, and the encapsulation mold.

The best possible sealing function can be supported by virtue of the fact that the surface is provided with a groove structure having longitudinally extended depressions and elevations lying alongside one another, which run in one direction.

It is particularly expedient in this case that in regions of the sealing region that have a longitudinal extent, the depressions and elevations are introduced transversely with respect to the direction of the longitudinal extent. In the region of these longitudinal extents, the encapsulation mold will also have a longitudinally extended sealing area. Consequently, the unevennesses will run transversely with respect to its longitudinal extent and the compensation between the most elevated part of the surface and the part of the surface lying at the lowest level is achieved in a greatest possible form.

The groove structure may have various cross-sections. An undulatory, a meandering or a zigzag cross-section is thus possible. All three cross-sectional forms or any further different cross-sectional form that has elevations and depressions has the effect that the material in the elevations passes into the depressions if the encapsulation mold presses onto the surface of the soldering resist.

Another possibility, in particular for the configuration of the directional independence of the sealing region consists in the fact that a grid structure is introduced in the surface, first depressions and elevations lying alongside one another, which run in a first direction crossing second depressions and elevations lying alongside one another, which run in a second direction.

In a further refinement, it is provided that the surface is either textured or applied in uneven fashion. In any event a nonuniform distribution of unevennesses and depressions is thus produced, as is known from the surface of orange peel.

A further embodiment, which enables a seal independently of the elasticity of the soldering resist, consists in the fact that the substrate surface has a layer made of elastic material in the sealing region. In particular, the layer may be arranged as an elevation. The elevation makes it possible for the seal also to be able to yield laterally, thereby supporting the sealing effect.

In principle, the elastic layer may be applied directly on the substrate, that is to say below the surface on which the soldering resist is applied. Another possibility consists in the fact that the layer made of elastic material is arranged on the surface of the soldering resist.

The aspect according to embodiments of the invention also provide a substrate in which, at the substrate surface on the solder ball side between the region in which an encapsulation mold that is to be emplaced during production can be placed on to the substrate surface of the solder ball side and the ball pads, a trench that prevents a material flow—occurring during production—from the mold compound in the direction of the ball pads is introduced into the substrate surface.

For security, it is also possible to realize both solutions, that is to say the arrangement of a sealing element and the arrangement of a trench in a substrate.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows an illustration of an FBGA component in cross-section as a demonstration of the prior art;

FIG. 2 shows a cross-section of the emplaced encapsulation molds for the molding of an FBGA component in accordance with FIG. 1, according to the prior art;

FIG. 3 shows a partial enlargement of the emplaced encapsulation mold onto the substrate surface in accordance with the prior art;

FIG. 4 shows a cross-section through an FBGA housing according to the invention in the region of the sealing area;

FIG. 5 shows the detail in accordance with FIG. 4 with an emplaced encapsulation mold;

FIG. 6 shows a plan view of a conductor structure configured according to the invention in the region of the sealing area;

FIG. 7 shows a partial illustration of the cross-section through an FBGA housing in the region of the sealing area with an elevation made of elastic material;

FIG. 8 shows an illustration of the cross-section in accordance with FIG. 7 with an emplaced encapsulation mold;

FIG. 9 shows a partial illustration of the cross-section through an FBGA housing with a trench in the region in which the encapsulation mold is emplaced;

FIG. 10 shows a partial illustration of the cross-section through an FBGA housing with a trench on that side of the substrate, which is remote from the sealing web; and

FIG. 11 shows an illustration like FIG. 10 with an emplaced encapsulation mold.

The following list of reference symbols can be used in conjunction with the figures:

| | |
|---|---|
| 1 | Substrate |
| 2 | Semiconductor chip |
| 3 | Conductor structure |
| 4 | Bonding wires |
| 5 | Bonding island on the semiconductor chip |
| 6 | Bonding island on the substrate |
| 7 | Ball pad |
| 8 | Solder ball |
| 9 | Chip side |
| 10 | Solder ball side |
| 11 | Bonding channel |
| 12 | Soldering resist mask |
| 13 | Upper housing part |
| 14 | Lower housing part |
| 15 | Upper encapsulation mold |
| 16 | Lower encapsulation mold |
| 17 | Sealing web |
| 18 | Breaking line |
| 19 | Encapsulation material |
| 20 | Resin constituent |
| 21 | Conductor track |
| 22 | Additional area element |
| 23 | Distance |
| 24 | Sealing area |
| 25 | Elevation |
| 26 | Region |
| 27 | Trench |
| 28 | Edge |
| F_{A} | Pressure force |

### DETAILED DESCRIPTION OF ILLUSTRATIVE EMBODIMENTS

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

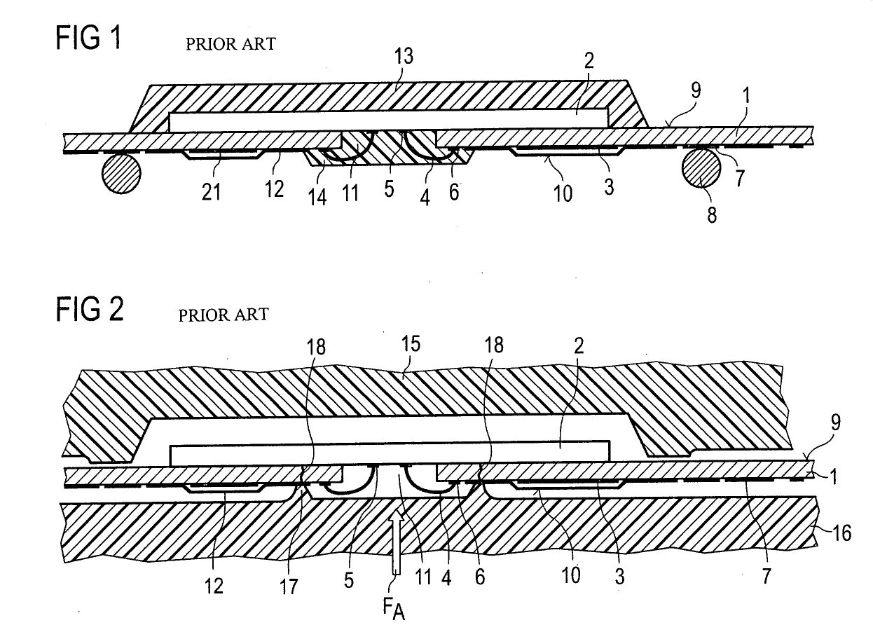

As illustrated in FIG. 1, an FBGA housing comprises a substrate 1, onto which a semiconductor chip 2 is mounted. The semiconductor chip 2 is electrically conductively connected to a conductor structure 3 on the substrate 1 via bonding wires 4. In this case, the bonding wires 4 are connected to bonding islands 5 on the semiconductor chip 2 at one end and to bonding islands 6 on the substrate 1 at the other end. The bonding islands 6 are part of the conductor structure 3. Ball pads 7 are likewise part of the conductor structure 3, the ball pads being provided with solder balls 8 for later connection to external conductor structures.

That side of the substrate 1 on which the semiconductor chip 2 is situated is referred to as chip side 9. That side of the substrate 1 on which the solder balls 8 are situated is referred to as solder ball side 10.

Alongside the solder balls 8, the conductor structure 3 is also arranged on the solder ball side 10. In order that the bonding wires 4 can be drawn from the semiconductor chip 2 to the bonding islands 6, provision is made of a bonding channel 11.

In order to prevent solder from subsequently flowing away from the solder balls 8, the solder ball side 10 of the substrate 1 is provided with a mask 12 made of a soldering resist.

For closure, the FBGA housing has an upper housing part 13 and a lower housing part 14.

As can be seen in FIG. 2, the two housing parts 13 and 14 are formed by an upper encapsulation mold 15 being placed onto the substrate 1 and a lower encapsulation mold 16 being placed on the solder ball side 10 of the substrate 1.

After these two encapsulation molds 15 and 16 have been emplaced, they are filled with an encapsulation material that is self-curing. As a result, in particular, the bonding wires 4 are protected by the lower encapsulation mold 16 or the lower housing part 14.

A pressure force F_{A} is exerted during the application of the lower encapsulation mold 16. The pressure force F_{A} serves to ensure that the sealing webs 17 of the lower encapsulation mold bear as tightly as possible on the substrate surface of the substrate 1 on the solder ball side 10.

As illustrated in FIG. 2, the pressure force F_{A} leads, in the first instance, very rapidly to a breaking of the substrate 1 along the breaking lines 18.

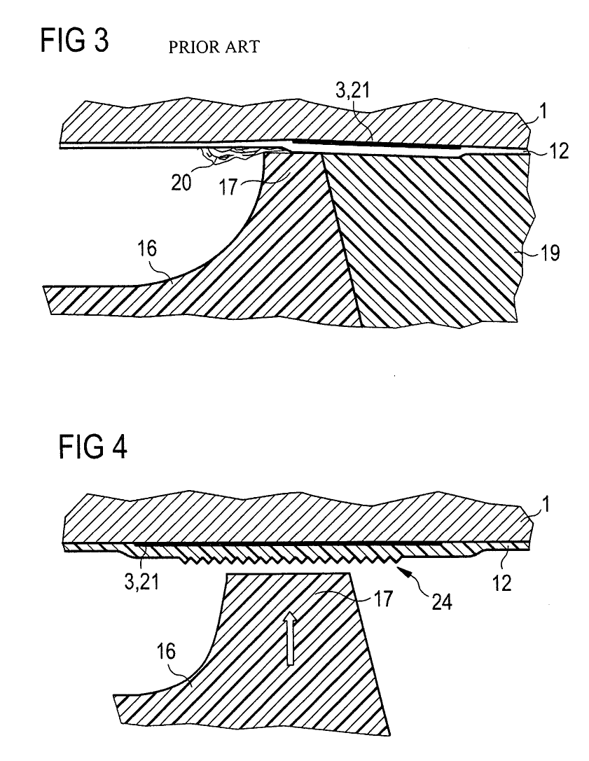

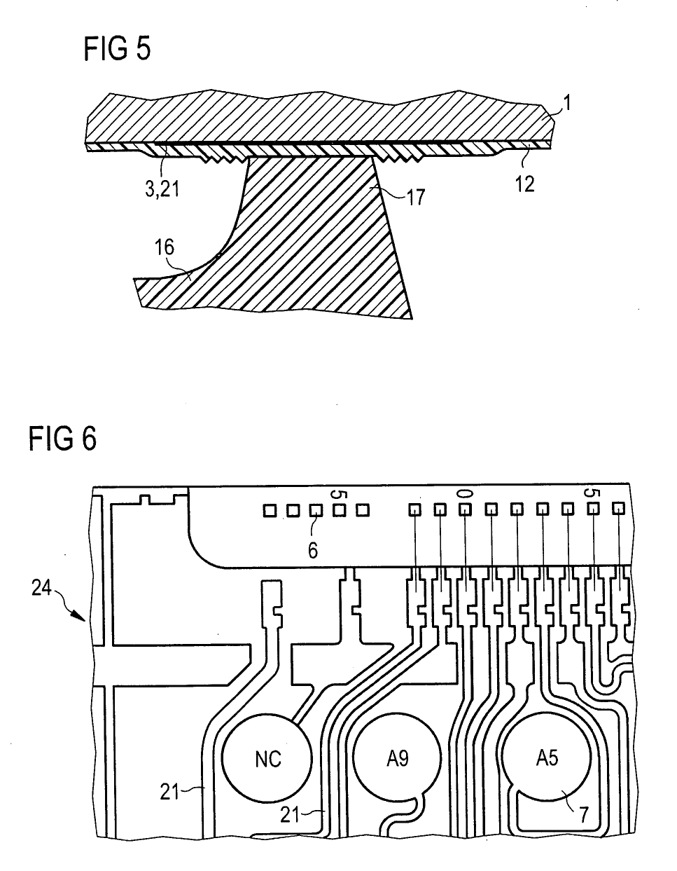

A further problem is illustrated in FIG. 3, which reveals that the sealing web 17 of the lower encapsulation mold 16 can usually bring about only an inadequate sealing between the surface of the soldering resist mask 12 (see FIG. 2) and the sealing web 17, with the result that “bleeding” of encapsulation material 19 can occur, that is to say that at least resin constituents 20 emerge in separated fashion from the encapsulation material 19.

An increase in the pressure force F_{A} will not lead to successful sealing in this case, particularly not when the sealing web 17 is supported on a boundary line between an edge of the conductor structure 3 and a region without a conductor structure.

However, even an increase in the pressure force will at best only intensify a break along the breaking lines 18.

As specified in FIG. 4, the conductor tracks 21 of the conductor structure 3 are provided with additional area elements 22. This makes it possible for the distances 23 between the individual conductor tracks 21 to be minimal and thus for virtually a closed area of the conductor structure 3 to be produced in the sealing region, that is to say in the region of the sealing area 24, which considerably facilitates the sealing operation.

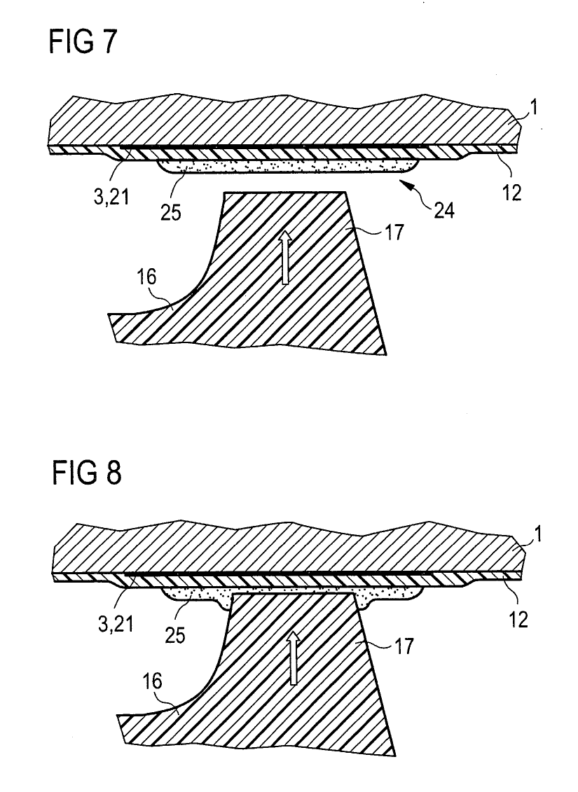

FIG. 7 illustrates an elevation 25 in the region of the sealing area 24 made of a flexible material.

As illustrated in FIG. 8, the elevation 25, upon emplacement of the sealing web 17 of the lower encapsulation mold 16, is deformed in a manner such that an optimum seal is achieved between lower encapsulation mold 16 and surface of the substrate 1, thereby effectively preventing bleeding.

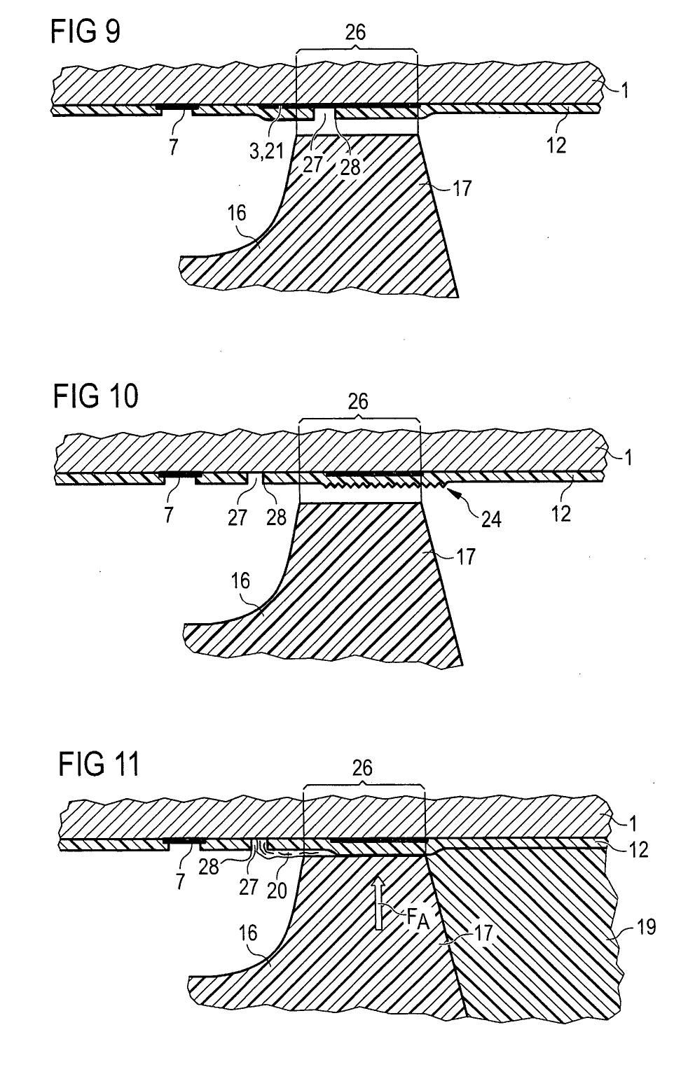

As illustrated in FIG. 9, in the region 26 in which the sealing web 17 of the lower encapsulation mold 16 is placed onto the solder ball side 10 of the substrate 1, a trench 27 is introduced into the soldering resist mask 12. For the rest, the surface of the soldering resist mask 12 and the sealing web 17 correspond to the prior art as illustrated in FIG. 3.

If the sealing web 17 is then pressed against the surface of the soldering resist mask 12 with the pressure force F_{A}, it is possible for resin constituents 20, as illustrated in FIG. 3, to emerge from the encapsulation material 19 between the soldering resist mask 12 and the sealing web 17. The resin constituents 20 are collected by the trench 27 by virtue of the solution in accordance with FIG. 9 and, consequently, can no longer pass into the vicinity of the ball pads 7.

As illustrated in FIG. 10, the surface of the soldering resist mask 12 is formed as a sealing area 24 in the region 26. A structure similar to that illustrated in FIG. 4 has been selected here. However, other embodiments, corresponding to FIG. 7, for example, are also possible.

At places at which the sealing web 17 does not bear completely on the sealing area, this may lead to “bleeding,” as is illustrated in FIG. 11.

In order, then, to prevent the situation where the resin constituents emerging in this case flow as far as the ball pads and make it more difficult to effect soldering there, a trench 27 is introduced into the soldering resist mask 12 alongside the region 26, to be precise on that side of the region 26, which is remote from the lower housing part 14.

As illustrated in FIG. 11, the trench 27 prevents the resin constituent 20 from flowing to the ball pads 7. This may be done in the first instance by virtue of the trench 27 directly taking up the resin constituent 20, or by the edges 28 of the trench 27 offering a resistance to the flowing on account of adhesion forces.

What is claimed is:

1. A method for producing an electronic component, the method comprising:
mounting a semiconductor chip on a chip side of a substrate, said semiconductor chip being electrically conductively connected to a conductor structure on the substrate;
applying solder balls to ball pads of the conductor structure on a solder ball side of the substrate;
applying a mask made of soldering resist to the solder ball side of the substrate;
forming an encapsulation mold to produce a lower housing part that is pressed onto the solder ball side of the substrate; and
filling the encapsulation mold with mold compound, wherein a surface of the substrate on the solder ball side, at least in the region in which the encapsulation mold is formed, is formed as a sealing region in such a way that the substrate surface is provided with seal elements with which the encapsulation mold enters into a sealing connection.

2. The method as claimed in claim 1, wherein the conductor structure is patterned in such a way that there is a minimum lateral distance between individual conductive tracks in the sealing region.

3. The method as claimed in claim 1, further comprising patterning a surface of the soldering resist in an uneven fashion at least in the sealing region.

4. The method as claimed in claim 3, wherein patterning the surface of the soldering resist comprises performing a photolithographic process.

5. The method as claimed in claim 3, wherein patterning the surface of the soldering resist comprises performing a milling operation.

6. The method as claimed in claim 3, wherein patterning the surface of the soldering resist comprises forming a groove structure in which longitudinally extended depressions and elevations lying alongside one another run in one direction.

7. The method as claimed in claim 6, wherein, in regions of the sealing region that have a longitudinal extent, the depressions and elevations are introduced transversely with respect to the direction of the longitudinal extent.

8. The method as claimed in claim 6, wherein the groove structure is provided with an undulatory, meandering or zigzag cross-section.

9. The method as claimed in claim 3, wherein patterning the surface of the soldering resist comprises forming a grid structure in the surface in a manner such that first depressions and elevations lying alongside one another and running in a first direction cross second depressions and elevations lying alongside one another and running in a second direction.

10. The method as claimed in claim 3, wherein patterning the surface of the soldering resist comprises texturing the surface.

11. The method as claimed in claim 1, further comprising exposing the soldering resist mask to a thermal process after application.

12. The method as claimed in claim 1, wherein a chemical or mechanical admixture that brings about unevennesses in the surface is added to the soldering resist before applying the mask.

13. The method as claimed in claim 3, wherein the mask of soldering resist is applied in uneven fashion.

14. The method as claimed in claim 1, further comprising applying a layer made of an elastic material to the substrate surface in the sealing region.

15. The method as claimed in claim 14, wherein the layer made of an elastic material is applied as an elevation.

16. The method as claimed in claim 14, wherein applying a layer made of an elastic material comprises applying the layer made of elastic material to the soldering resist.

17. A method for producing an electronic component, the method comprising:
mounting a semiconductor chip on a chip side of a substrate, said semiconductor chip being electrically conductively connected to a conductor structure on the substrate,
applying solder balls to ball pads of the conductor structure on a solder ball side of the substrate;
applying a soldering resist mask to the solder ball side of the substrate;
forming an encapsulation mold at a surface of the solder ball side of the substrate;
filling the encapsulation mold with mold compound; and
forming a trench in the substrate surface on the solder ball side between the region in which the encapsulation mold is formed, the trench preventing a flow of material from the mold compound in the direction of the ball pads.

18. The method as claimed in claim 17, wherein the trench is formed as a trench running around a region in which the encapsulation mold is formed on the substrate surface.

19. The method as claimed in claim 17, wherein the trench is at least partially formed at an uneven region of the substrate surface.

20. The method as claimed in claim 17, further comprising forming a second trench parallel to the trench.

21. The method as claimed in claim 17, wherein the trench is formed in the soldering resist layer.

22. The method as claimed in claim 17, wherein the trench includes trench edges that lie between the substrate surface and trench walls, the trench edges being formed in sharp-edged fashion.

23. The method as claimed in claim 17, wherein the trench is formed with a trench height to trench width ratio of between about 1 to 1 and 1 to 3.

24. The method as claimed in claim 17, forming a trench comprises performing a photolithographic process.

25. The method as claimed in claim 24, wherein forming a trench comprises, during the production of the mask made from the soldering resist, first applying a resist layer over the entire solder ball side and subsequently patterning said resist layer by means of a photolithographic process, the trench being introduced together with other openings into the resist layer.

26. The method as claimed in claim 17, wherein the trench is patterned by means of a milling operation.

27. A method for producing an FBGA component, the method comprising:
mounting a semiconductor chip on a chip side of a substrate, said semiconductor chip being electrically conductively connected to a conductor structure on the substrate;
applying solder balls to ball pads of the conductor structure on a solder ball side of the substrate;
applying mask made of solder resist to the solder ball side of the substrate;
forming an encapsulation mold at a surface of the solder ball side of the substrate;
filling the encapsulation mold with mold compound; and
forming a trench in the substrate surface on the solder ball side between the region in which the encapsulation mold is formed, the trench preventing a flow of material from the mold compound in the direction of the ball pads;
wherein the substrate surface on the solder ball side, at least in the region in which the encapsulation mold is formed, is formed as a sealing region in such a way that the substrate surface is provided with seal elements with which the encapsulation mold enters into a sealing connection.

28. A semiconductor component comprising:
a substrate having a chip side and a solder ball side;
a semiconductor chip mounted on the chip side of a substrate, said semiconductor chip being electrically conductively connected to a conductor structure on the substrate;
ball pads disposed over the solder ball side of the substrate, the ball pads electrically conductively connected to the conductor structure and suitable for application of solder balls;
a mask made from a soldering resist disposed on the solder ball side; and
a sealing region at a surface of the solder ball side of the substrate, the sealing region being provided with seal elements for a sealing connection to an encapsulation mold on the surface of the solder ball side.

29. The semiconductor component as claimed in claim 28, wherein the conductor structure is patterned in such a way that there is a minimum lateral distance between individual conductive tracks in the sealing region.

30. The semiconductor component as claimed in claim 28, wherein a surface of the soldering resist is patterned in an uneven fashion at least in the sealing region.

31. The semiconductor component as claimed in claim 30, wherein the surface is provided with a groove structure having longitudinally extended depressions and elevations lying alongside one another, which run in one direction.

32. The semiconductor component as claimed in claim 31, wherein, at regions of the sealing region that have a longitudinal extent, the depressions and elevations are introduced transversely with respect to a direction of the longitudinal extent.

33. The semiconductor component as claimed in claim 31, wherein the groove structure has an undulatory, meandering or zigzag cross-section.

34. The semiconductor component as claimed in claim 30, wherein the surface has a grid structure, first depressions and elevations lying alongside one another and running in a first direction crossing second depressions and elevations lying alongside one another and running in a second direction.

35. The semiconductor component as claimed in claim 28, wherein a surface of the soldering resist is uneven.

36. The semiconductor component as claimed in claim 35, wherein the surface of the soldering resist is textured.

37. The semiconductor component as claimed in claim 28, further comprising a layer made of an elastic material disposed on the substrate surface in the sealing region.

38. The semiconductor component as claimed in claim 37, wherein the layer is arranged as an elevation.

39. The semiconductor component as claimed in claim 37, wherein the layer made from elastic material is arranged on the soldering resist.

40. A semiconductor component comprising:
a substrate having a chip side and a solder ball side;
a semiconductor chip mounted on the chip side of a substrate, said semiconductor chip being electrically conductively connected to a conductor structure on the substrate;
ball pads disposed over the solder ball side of the substrate, the ball pads electrically conductively connected to the conductor structure and suitable for application of solder balls; and
a mask made from a soldering resist on the solder ball side of the substrate, wherein the mask includes a trench formed therein, the trench located at the substrate surface on the solder ball side between a region in which an encapsulation mold that is to be formed during production can be placed onto the substrate surface of the solder ball side and the ball pads.

41. The semiconductor component as claimed in claim 40, wherein the trench comprises a trench running around the region in which the encapsulation mold is placed onto the substrate surface of the solder ball side.

42. The semiconductor component as claimed in claim 40, wherein the trench is partially arranged at locations at which the substrate surface is uneven.

43. The semiconductor component as claimed in claim 40, wherein a second trench is introduced parallel alongside the trench.

44. The semiconductor component as claimed in claim 40, wherein the trench includes trench edges that lie between the substrate surface and trench walls, the trench edges being formed in sharp-edged fashion.

45. The semiconductor component as claimed in claim 40, wherein the trench is formed with a trench height to trench width ratio between about 1 to 1 and 1 to 3.

46. The semiconductor component as claimed in claim 40, wherein the trench prevents a material flow—occurring during production—from the mold compound in the direction of the ball pads.

47. An FBGA component comprising:
a substrate having a chip side and a solder ball side;
a semiconductor chip mounted on the chip side of a substrate, said semiconductor chip being electrically conductively connected to a conductor structure on the substrate;
ball pads disposed over the solder ball side of the substrate, the ball pads electrically conductively connected to the conductor structure and suitable for application of solder balls; and
a mask made from a soldering resist on the solder ball side of the substrate, wherein the mask includes a trench formed therein, the trench located at the substrate surface on the solder ball side between a region in which an encapsulation mold that is to be formed during production can be placed onto the substrate surface of the solder ball side and the ball pads;
wherein the substrate surface on the solder ball side, at least in the region in which the encapsulation mold is formed, is formed as a sealing region in such a way that the substrate surface is provided with seal elements with which the encapsulation mold enters into a sealing connection.

48. The semiconductor component as claimed in claim 47, wherein the conductor structure is patterned in such a way that there is a minimum lateral distance between the individual conductive tracks in the sealing region.

49. The semiconductor component as claimed in claim 47, wherein the surface of the soldering resist is patterned in uneven fashion at least in the sealing region.

50. The semiconductor component as claimed in claim 47, further comprising a layer made of an elastic material applied to the substrate surface in the sealing region.

51. The semiconductor component as claimed in claim 47, wherein the trench is formed as a trench running around the region in which the encapsulation mold is placed onto the substrate surface of the solder ball side.

52. The semiconductor component as claimed in claim 47, wherein the trench is partially arranged at locations at which the substrate surface is uneven.

53. The semiconductor component as claimed in claim 47, wherein a second trench is disposed parallel to the trench.

54. The semiconductor component as claimed in claim 47, wherein the trench is introduced into the soldering resist layer.

55. The semiconductor component as claimed in claim 47, wherein the trench includes trench edges that lie between the substrate surface and trench walls, the trench edges being formed in sharp-edged fashion.

56. The semiconductor component as claimed in claim 47, wherein the trench is formed with a trench height to trench width ratio between about 1 to 1 and 1 to 3.
